(19) United States
(12) Patent Application Publication
(10) Pub. No.: US 2026/0372047 A1
(43) Pub. Date: Nov. 19, 2026

(54) PACKAGE STRUCTURE

(71) Applicant: Taiwan Semiconductor Manufacturing Company, Ltd., Hsinchu (TW)

(72) Inventors: Ke-Han SHEN, Chiayi City (TW); Chih-Yuan CHEN, Hsinchu County (TW); Jiung WU, Taoyuan City (TW); Hung-Yi KUO, Taipei City (TW); Chung-Ju LEE, Hsinchu City (TW); Tung-He CHOU, Hsinchu City (TW); Ji CUI, Bolingbrook, IL (US); Kuo-Chung YEE, Taoyuan City (TW); Chen-Hua YU, Hsinchu City (TW); Cheng-Chieh HSIEH, Tainan (TW); Yu-Jen LIEN, Tainan City (TW); Yian-Liang KUO, Hsinchu City (TW); Shih-Hao TSENG, Hsinchu City (TW); Jen Yu WANG, Hsinchu City (TW); Tzu-Chieh CHOU, Hsinchu City (TW)

(73) Assignee: Taiwan Semiconductor Manufacturing Company, Ltd., Hsinchu (TW)

(21) Appl. No.: 19/752,153

(22) Filed: Jul. 23, 2026

Related U.S. Application Data
(62) Division of application No. 18/360,666, filed on Jul. 27, 2023.

(51) Int. Cl. H10W 20/20; H10D 30/43; H10D 30/67; H10D 62/10; H10W 20/00; H10W 72/00; H10W 80/00; H10W 90/00

(52) U.S. Cl. CPC H10W 20/20; H10D 30/43; H10D 30/6735; H10D 62/121; H10W 20/023; H10W 72/019; H10W 80/312; H10W 80/327; H10W 90/792

(57) ABSTRACT

A package structure and a method for forming the same are provided. The package structure includes a first package structure and a second package structure. The first package structure includes a first device formed over a first substrate. The first device includes a first conductive plug connected to a through substrate via (TSV) structure formed in the first substrate. A buffer layer surrounds the first substrate. A first bonding layer is formed over the first substrate and the buffer layer. The second package structure includes a second device formed over a second substrate. A second bonding layer is formed over the second device. A hybrid bonding structure is between the first package structure and the second package structure by bonding the first bonding layer to the second bonding layer.

### CROSS REFERENCE TO RELATED APPLICATIONS

This Application is a Divisional application of U.S. patent application Ser. No. 18/360,666, filed on Jul. 27, 2023, the entirety of which is incorporated by reference herein.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

New packaging technologies, such as package on package (PoP), have been developed, in which a top package with a device die is bonded to a bottom package, with another device die. By adopting these new packaging technologies, various packages with different or similar functions can be integrated together.

Although existing package structures and methods of fabricating a package structure have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1H show perspective representations of various stages of forming a semiconductor structure, in accordance with some embodiments of the disclosure.

FIGS. 2A-2C illustrate cross-sectional representations of various stages of manufacturing the semiconductor structure shown along line A-A’ in FIG. 1H after FIG. 1H, in accordance with some embodiments.

FIGS. 3A-3B illustrate cross-sectional representations of various stages of manufacturing the semiconductor structure shown along line B-B’ in FIG. 1H after FIG. 2B, in accordance with some embodiments.

FIG. 4 illustrates a cross-sectional representation of the semiconductor structure shown along line C-C’ in FIG. 1H, in accordance with some embodiments.

FIGS. 5A-5F illustrate cross-sectional representations of various stages of manufacturing a package structure, in accordance with some embodiments.

FIG. 5C’ is a top-view of FIG. 5C of the package structure, in accordance with some embodiments.

FIG. 6A illustrates a cross-sectional representation of an enlarged semiconductor structure of FIG. 5A, in accordance with some embodiments.

FIG. 6B illustrates a cross-sectional representation of an enlarged semiconductor structure of FIG. 5E, in accordance with some embodiments.

FIG. 6C illustrates a cross-sectional representation of an enlarged semiconductor structure of FIG. 5F, in accordance with some embodiments.

FIGS. 7A-7B illustrate cross-sectional representations of various stages of manufacturing a package structure, in accordance with some embodiments.

FIGS. 8A-8C illustrate cross-sectional representations of various stages of manufacturing a package structure, in accordance with some embodiments.

FIGS. 9A-9F illustrate cross-sectional representations of various stages of manufacturing a package structure, in accordance with some embodiments.

FIGS. 10A-10F illustrate cross-sectional representations of various stages of manufacturing a package structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments for a package structure and method for forming the same are provided. The package structure includes packaging a first die with a semiconductor structure into a second die. The semiconductor structure includes a device over a substrate in a wafer level, and a conductive plug formed in the substrate. The individual semiconductor structures (or integrated circuits (IC)) on the wafer can be tested through a wafer test system, before they are separated or “diced” from the wafer for packaging. After passing the test, a known good die which has no defects in the integrated circuit (IC) chip is diced from the wafer.

The substrate of the known good die is turned upside down and placed over a carrier substrate. The backside of the substrate of the die is exposed, and a buffer layer is formed over the backside surface of the substrate. The buffer layer is used to improve the polishing uniformity of the substrate during the planarization process (e.g. CMP process). A planarization process is performed on a portion of the buffer layer and a portion of the substrate to form a thinned substrate. The TSV structures are formed in the thinned substrate to connect the conductive plug which is formed before the planarization process. Since the die is a known good die, and the polishing uniformity of the substrate is controlled well by the help of the buffer layer. Therefore, the yield, the quality and reliability of the package structure are improved.

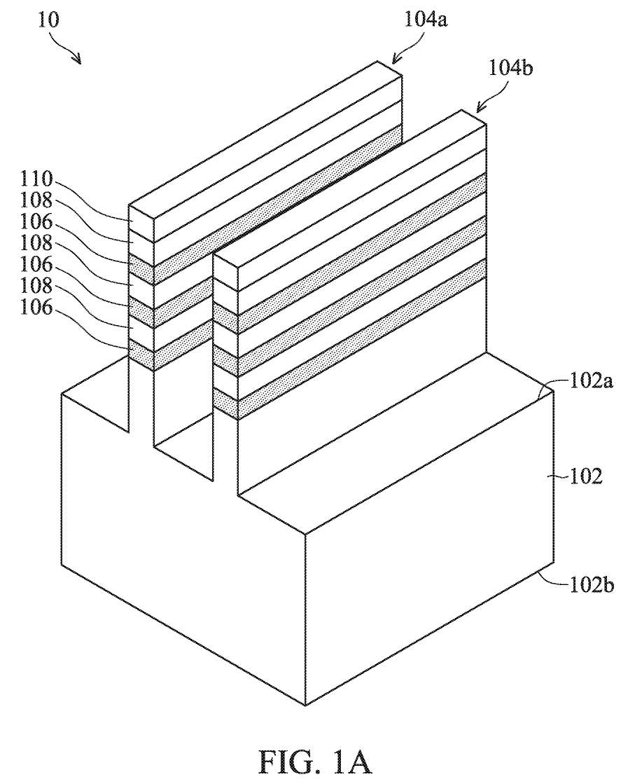

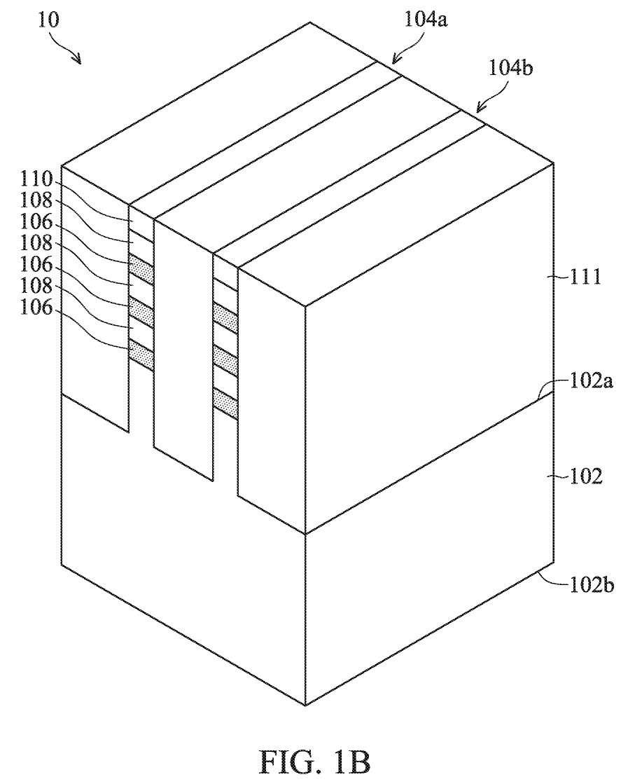

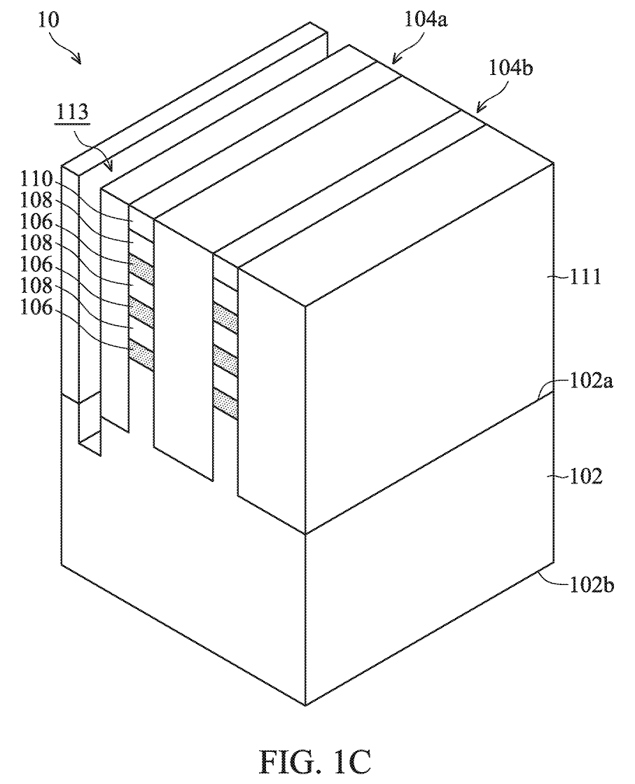

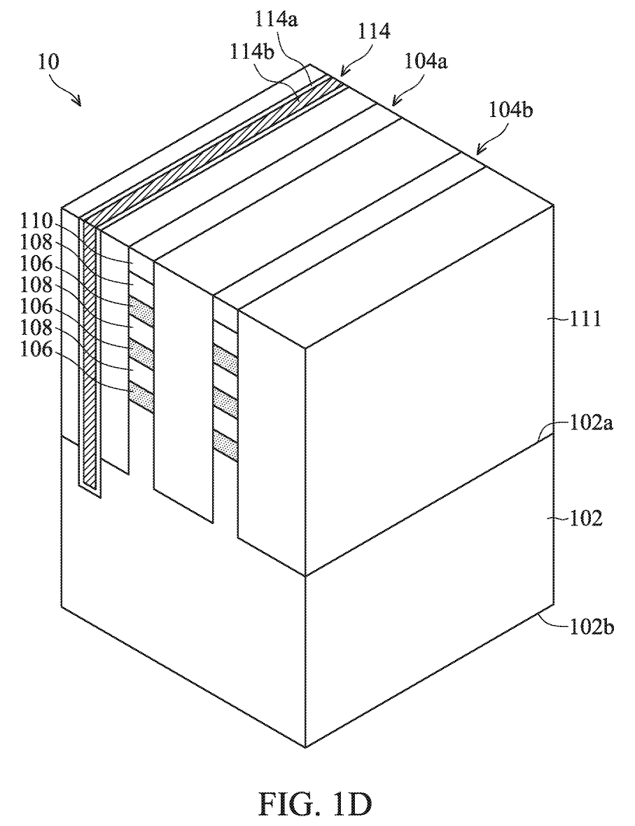

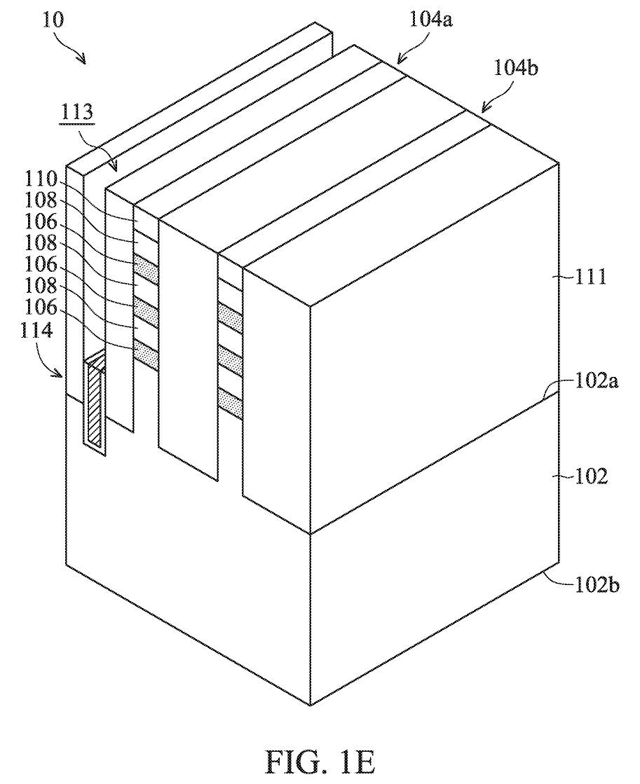

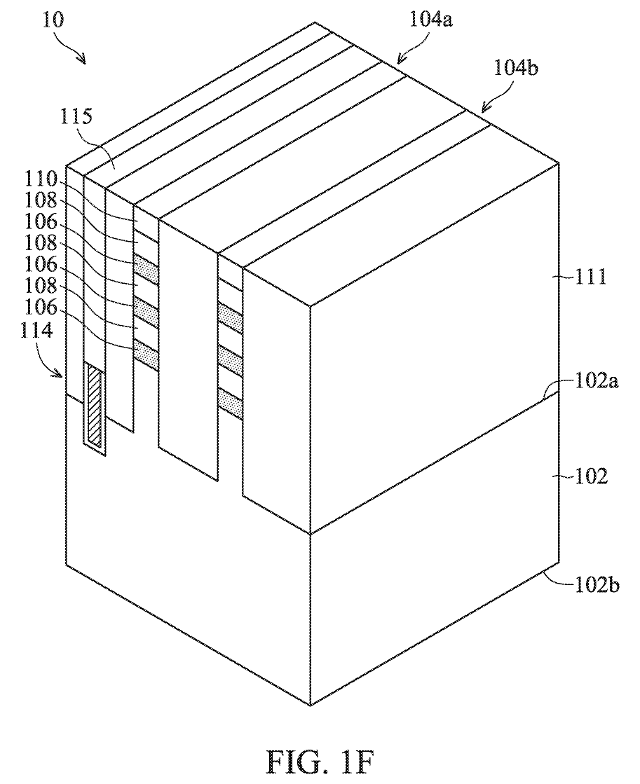

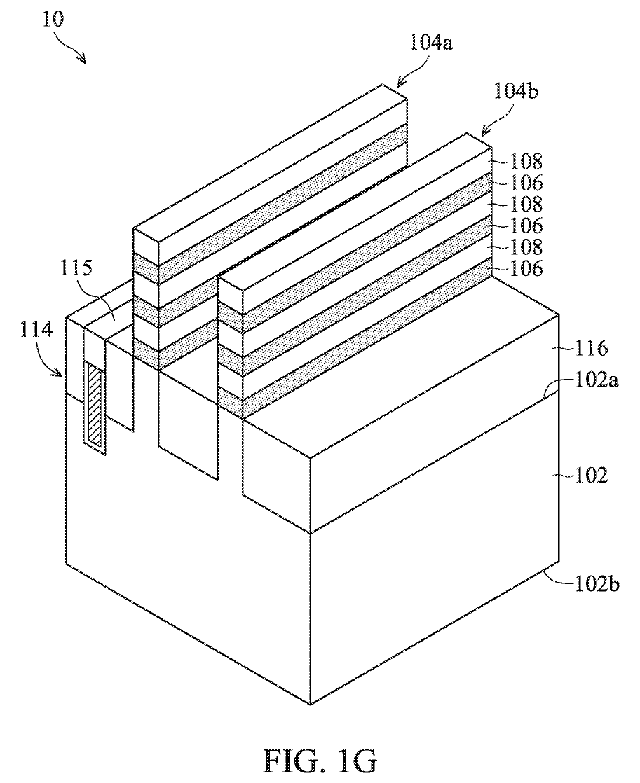

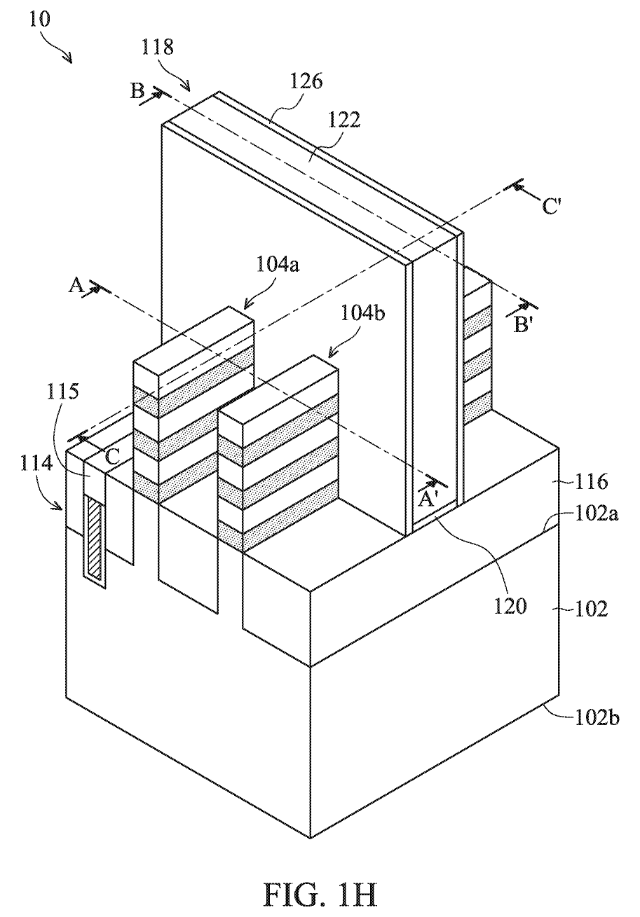

FIGS. 1A-1H show perspective representations of various stages of forming a semiconductor structure 10, in accordance with some embodiments of the disclosure.

As shown in FIG. 1A, first semiconductor material layers 106 and second semiconductor material layers 108 are formed over a substrate 102. The substrate 102 includes a front side surface 102a and a backside surface 102b. The first semiconductor material layers 106 and second semiconductor material layers 108 are formed over the front side surface 102a of the substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Afterwards, after the first semiconductor material layers 106 and the second semiconductor material layers 108 are formed as a semiconductor material stack over the substrate 102, the semiconductor material stack is patterned to form a first fin structure 104a and a second fin structure 104b, in accordance with some embodiments. In some embodiments, each of the first fin structure 104a and a second fin structure 104b includes a base fin structure and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer and a nitride layer formed over the pad oxide layer. The pad oxide layer may be made of silicon oxide, which is formed by thermal oxidation or chemical vapor deposition (CVD), and the nitride layer may be made of silicon nitride, which is formed by chemical vapor deposition (CVD), such as low-temperature chemical vapor deposition (LPCVD) or plasma-enhanced CVD (PECVD).

Next, as shown in FIG. 1B, after the first fin structure 104a and the second fin structure 104b is formed, an isolation material 111 is formed around first fin structure 104a and the second fin structure 104b, in accordance with some embodiments. Next, a portion of the isolation material 111 and the mask structure 110 are removed by a planarization process such as CMP process.

The isolation material 111 is made of low-k dielectric material with dielectric constant (K value) in a range from about 1 to about 5. In some embodiments, the isolation material 111 is made of silicon oxide, silicon nitride, silicon oxynitride (SiON), another applicable insulating material, or a combination thereof. In some embodiments, the isolation material 111 is formed by a LPCVD process, plasma enhanced CVD (PECVD) process, high density plasma CVD (HDP-CVD) process, high aspect ratio process (HARP) process, flowable CVD (FCVD) process, atomic layer deposition (ALD) process, another suitable method, or a combination thereof.

Next, as shown in FIG. 1C, a trench 113 is formed through the isolation material 11 and a portion of the substrate 102, in accordance with some embodiments. The trench 113 is formed by an etching process, such as a dry etching process or a wet etching process.

Afterwards, as shown in FIG. 1D, a barrier layer 114a and a conductive layer 114b are formed in the trench 113, in accordance with some embodiments. A conductive plug 114 is constructed by the barrier layer 114a and the conductive layer 114b. In some embodiments, the conductive plug 114 is formed to connect to power rail.

The barrier layer 114a is made of titanium (Ti), titanium nitride (TiN), tantalum (Ta), tantalum nitride (TaN), or another applicable material. In some embodiments, the barrier layer 114a is formed by using a process such as chemical vapor deposition (CVD), physical vapor deposition (PVD), plasma enhanced CVD (PECVD), plasma enhanced physical vapor deposition (PEPVD), atomic layer deposition (ALD), or another applicable deposition process.

The conductive layer 114b may be made of conductive material. In some embodiments, the conductive layer 114b is made of tungsten (W), ruthenium (Ru), molybdenum (Mo), or the like. In some embodiments, the conductive layer 114b is formed by performing a deposition process, such as chemical vapor deposition (CVD), physical vapor deposition, (PVD), atomic layer deposition (ALD), or another applicable process.

Next, as shown in FIG. 1E, the top portion of the conductive plug 114 is removed, in accordance with some embodiments. As a result, the trench 113 is exposed. The isolation material 111 is exposed by the trench 113. In some embodiments, the top portion of the conductive plug 114 is removed by an etching process, such as a dry etching process or a wet etching process.

Afterwards, as shown in FIG. 1F, a dielectric plug 115 is filled into the trench 113, in accordance with some embodiments. The dielectric plug 115 may include silicon oxide, silicon carbide, silicon nitride, silicon oxynitride, one or more other suitable materials, or a combination thereof. In some embodiments, the dielectric plug 115 is formed by performing a deposition process, such as chemical vapor deposition (CVD), physical vapor deposition, (PVD), atomic layer deposition (ALD), or another applicable process.

Next, as shown in FIG. 1G, a portion of the isolation material 111 and a portion of the dielectric plug 115 are removed to form an isolation structure 116, in accordance with some embodiments. The top surface of the isolation structure 116 is substantially coplanar with the top surface of the dielectric plug 115.

The isolation structure 116 is configured to electrically isolate active regions (e.g. the fin structure 104) of the semiconductor device structure 10 and is also referred to as shallow trench isolation (STI) feature in accordance with some embodiments.

Afterwards, as shown in FIG. 1H, a dummy gate structure 118 is formed over the first fin structure 104a and the second fin structure 104b and over the isolation structure 116, in accordance with some embodiments.

In some embodiments, the dummy gate structure 118 includes a dummy gate dielectric layer 120 and a dummy gate electrode layer 122. In some embodiments, the dummy gate dielectric layer 120 is made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 120 is formed using thermal oxidation, chemical vapor deposition (CVD), atomic vapor deposition (ALD), physical vapor deposition (PVD), another suitable method, or a combination thereof. In some embodiments, the dummy gate dielectric layer 120 is made of conductive material. The conductive material includes polycrystalline-silicon (poly-Si), poly-crystalline silicon-germanium (poly-SiGe), metallic nitrides, metallic silicides, metals, or a combination thereof. In some embodiments, the dummy gate electrode layer 122 is formed using chemical vapor deposition (CVD), physical vapor deposition (PVD), or a combination thereof.

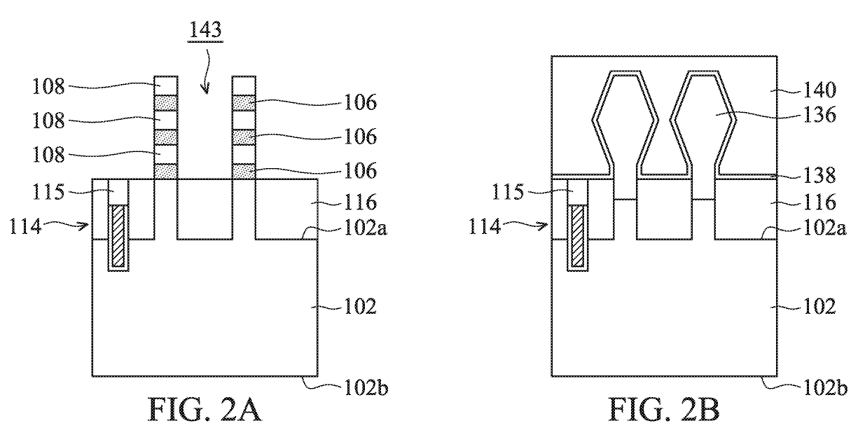

FIGS. 2A-2C illustrate cross-sectional representations of various stages of manufacturing the semiconductor structure 10 shown along line A-A’ in FIG. 1H after FIG. 1H, in accordance with some embodiments.

As shown in FIG. 2A, the first fin structure 104a and the second fin structure 104b are formed over the substrate 102 and extend above the isolation structure 116, in accordance with some embodiments. .

Next, as shown in FIG. 2B, the top portions of the first fin structure 104a and the top portion of the second fin structure 104b are removed to form S/D recesses (not shown) in the S/D region, in accordance with some embodiments. The source/drain (S/D) region(s) may refer to a source or a drain, individually or collectively dependent upon the context.

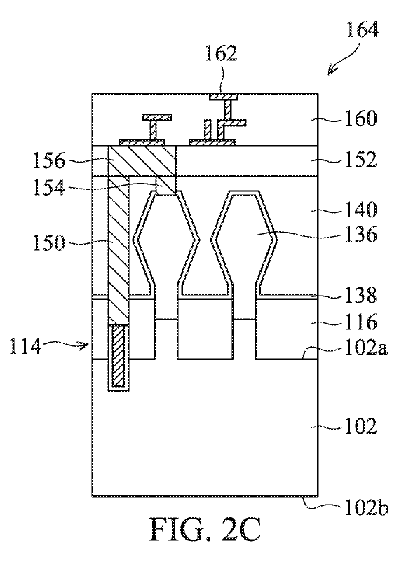

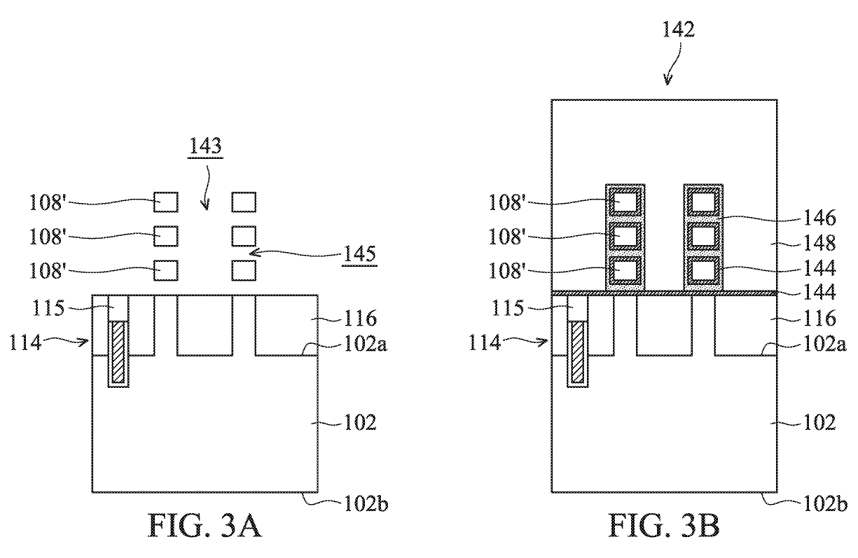

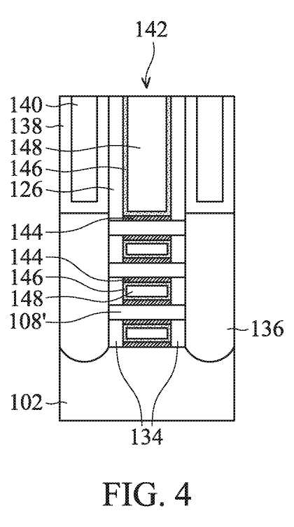

After the source/drain (S/D) recesses are formed, the first semiconductor material layers 106 exposed by the source/drain (S/D) recesses are laterally recessed to form notches (not shown), in accordance with some embodiments. Next, inner spacers 134 (shown in FIG. 4) are formed in the notches between the second semiconductor material layers 108, in accordance with some embodiments. The inner spacers 134 are configured to separate the source/drain (S/D) structures and the gate structures formed in subsequent manufacturing processes in accordance with some embodiments. In some embodiments, the inner spacers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layer 134 is formed by a deposition process, such as chemical vapor deposition (CVD) process, atomic layer deposition (ALD) process, another applicable process, or a combination thereof.

Next, after the inner spacers 134 are formed, the source/drain (S/D) structures 136 are formed in the S/D recesses, in accordance with some embodiments. In some embodiments, the S/D structures 136 are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the S/D structures 136 are made of any applicable material, such as Ge, Si, GaAs, AlGaAs, SiGe, GaAsP, SiP, SiC, SiCP, or a combination thereof.

In some embodiments, the S/D structures 136 are in-situ doped during the epitaxial growth process. For example, the S/D structures 136 may be the epitaxially grown SiGe doped with boron (B). For example, the S/D structures 136 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the S/D structures 136 are doped in one or more implantation processes after the epitaxial growth process.

Next, after the S/D structures 136 are formed, a contact etch stop layer (CESL) 138 is conformally formed to cover the S/D structures 136 and an interlayer dielectric (ILD) layer 140 is formed over the contact etch stop layers 138, in accordance with some embodiments.

In some embodiments, the CESL 138 is made of a dielectric materials, such as silicon nitride, silicon oxide, silicon oxynitride, another suitable dielectric material, or a combination thereof. The dielectric material for the CESL 138 may be conformally deposited over the semiconductor device structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the CESL 138 and the ILD layer 140 are deposited, a planarization process such as CMP or an etch-back process may be performed until the gate electrode layers 122 of the dummy gate structures 118 are exposed, as shown in FIG. 2B, in accordance with some embodiments.

FIGS. 3A-3B illustrate cross-sectional representations of various stages of manufacturing the semiconductor structure 10 shown along line B-B’ in FIG. 1H after FIG. 2B, in accordance with some embodiments.

As shown in FIG. 3A, after the ILD layer 140 is formed, the dummy gate structure 118 is replaced with a gate structure 142, in accordance with some embodiments. The gate structure 142 is formed along the second direction (e.g. Y-axis).

More specifically, the dummy gate structure 118 is removed to form a trench 143, and the first semiconductor material layers 106 are removed to from a trench 145. As a result, nanostructures 108’ with the second semiconductor material layers 108 are formed, in accordance with some embodiments. The S/D structure 136 is attached to the nanostructures 108’.

The removal process may include one or more etching processes. For example, when the dummy gate electrode layers 122 are polysilicon, a wet etchant such as a tetramethylammonium hydroxide (TMAH) solution may be used to selectively remove the dummy gate electrode layers 122. Afterwards, the dummy gate dielectric layers 120 may be removed using a plasma dry etching, a dry chemical etching, and/or a wet etching. The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions. In some embodiments, the upper portions of the gate spacers 126 are also removed.

After the nanostructures 108’ are formed, the gate structure 142 is formed wrapped around the nanostructures 108’. The gate structure 142 wraps around the nanostructures 108’ to form gate-all-around transistor structures in accordance with some embodiments. In some embodiments, the gate structure 142 includes an interfacial layer 144, a gate dielectric layer 146, and a gate electrode layer 148.

In some embodiments, the interfacial layers 144 are oxide layers formed around the nanostructures 108’ and on the top of the base fin structure. In some embodiments, the interfacial layers 144 are formed by performing a thermal process.

In some embodiments, the gate dielectric layers 146 are formed over the interfacial layers 144, so that the nanostructures 108’ are surrounded (e.g. wrapped) by the gate dielectric layers 146. In addition, the gate dielectric layers 146 also cover the sidewalls of the gate spacers 126 and the inner spacers 134 in accordance with some embodiments. In some embodiments, the gate dielectric layers 146 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂-Al2O₃) alloy, another suitable high-k dielectric material, or a combination thereof. In some embodiments, the gate dielectric layers 146 are formed using chemical vapor deposition (CVD), atomic layer deposition (ALD), another applicable method, or a combination thereof.

In some embodiments, the gate electrode layers 148 are formed on the gate dielectric layer 146. In some embodiments, the gate electrode layers 148 are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layers 148 are formed using chemical vapor deposition (CVD), atomic layer deposition (ALD), electroplating, another applicable method, or a combination thereof. Other conductive layers, such as work function metal layers, may also be formed in the gate structures 142, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

After the interfacial layers 144, the gate dielectric layers 146, and the gate electrode layers 148 are formed, a planarization process such as CMP or an etch-back process may be performed until the ILD layer 140 is exposed.

FIG. 4 illustrates a cross-sectional representation of the semiconductor structure 10 shown along line C-C’ in FIG. 1H, in accordance with some embodiments.

FIG. 4 shows the semiconductor structure 10 after the gate structure 142 is formed. The inner spacers 134 are formed between the S/D structure 136 and the gate structure 142. The gate spacers 126 are formed on opposite sidewall surfaces of the gate structure 142. The inner spacer 134 are formed directly below the gate spacers 126. The nanostructures 108’ are surrounded by the gate structure 142.

Next, referring to FIG. 2C again, after the gate structure 142 is formed, a conductive plug 150 is formed through the ILD layer 140, and a dielectric layer 152 is formed over the ILD layer 140, in accordance with some embodiments. Next, a silicide layer 154 and an S/D contact structure 156 are formed over the S/D structure 136. The conductive plug 150 is formed on and is electrically connected to the conductive plug 114. The conductive plug 150 is electrically connected to the S/D contact structure 156 and the conductive plug 114.

The conductive plug 150 is formed by forming an opening through the ILD layer 140, the contact etch stop layer 138, the dielectric plug 115 and the isolation structure 116 to expose the conductive plug 114. Next, a barrier layer and a conductive material are formed in the opening to form the conductive plug 150.

The dielectric layer 152 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 152 may be formed by chemical vapor deposition (CVD), physical vapor deposition, (PVD), atomic layer deposition (ALD), or other applicable processes.

In some embodiments, the contact openings may be formed through the contact etch stop layer 138, the ILD layer 140, and the dielectric layer 152 to expose the top surfaces of the S/D structures, and then the silicide layers 154 and the S/D contact structure 156 may be formed in the contact openings. The contact openings may be formed using a photolithography process and an etching process. In addition, some portions of the S/D structure exposed by the contact openings may also be etched during the etching process.

The silicide layers 154 may be formed by forming a metal layer over the top surfaces of the S/D structure 136 and annealing the metal layer so the metal layer reacts with the S/D structure 136 to form the silicide layers 154. The unreacted metal layer may be removed after the silicide layers 154 are formed.

The S/D contact structure 156 may include a barrier layer and a conductive layer. In some other embodiments, the S/D contact structure 156 does not include a barrier layer. In some embodiments, the barrier layer is made of titanium (Ti), titanium nitride (TiN), tantalum (Ta), tantalum nitride (TaN), or another applicable material. In some embodiments, the barrier layer is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. In some embodiments, the conductive layer is made of tungsten (W), ruthenium (Ru), molybdenum (Mo), or the like. In some embodiments, the conductive layer is formed by performing a deposition process, such as chemical vapor deposition (CVD), physical vapor deposition, (PVD), atomic layer deposition (ALD), or other applicable processes.

Next, an interconnect structure 164 is formed over the dielectric layer 152. The interconnect structure 164 may be used as a redistribution (RDL) structure for routing. The interconnect structure 164 includes multiple conductive layers 162 formed in multiple dielectric layers 160. The conductive plug 114 is electrically connected to the conductive layer 162 of the interconnect structure 160 by the conductive plug 150 and the S/D contact structure 156.

The conductive layers 162 are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive layers 162 are formed by electroplating, electroless plating, printing, a chemical vapor deposition (CVD) process, or a physical vapor deposition (PVD) process.

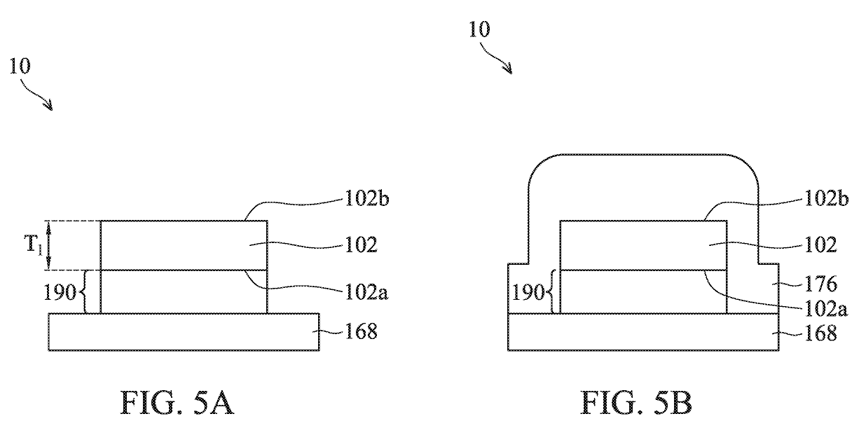

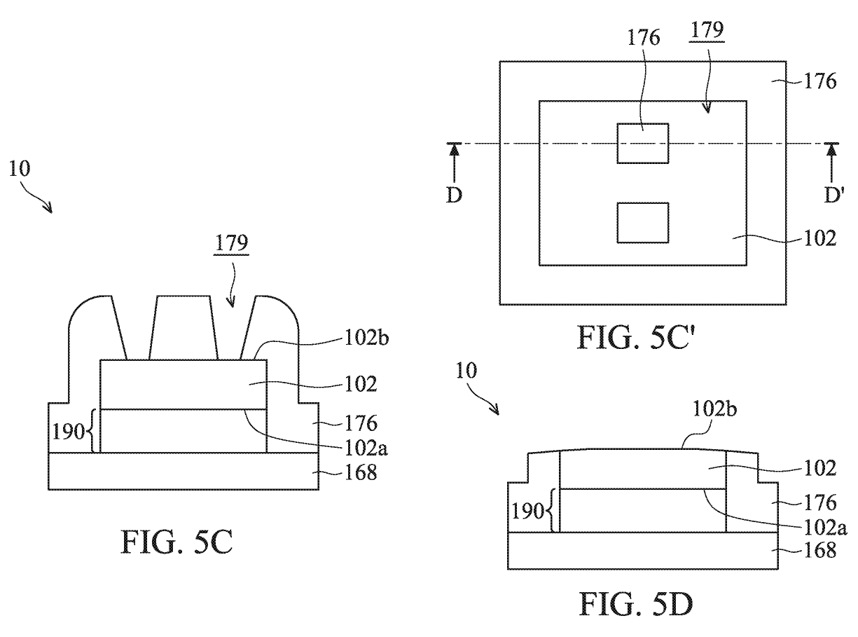

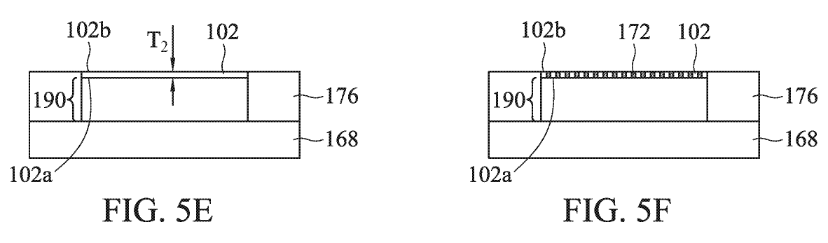

FIGS. 5A-5F illustrate cross-sectional representations of various stages of manufacturing a package structure 100a, in accordance with some embodiments. FIG. 5C’ is a top-view of FIG. 5C of the package structure 100a, in accordance with some embodiments. FIG. 5C is a cross-sectional representation of the package structure 100a along line DD’ of FIG. 5C’, in accordance with some embodiments.

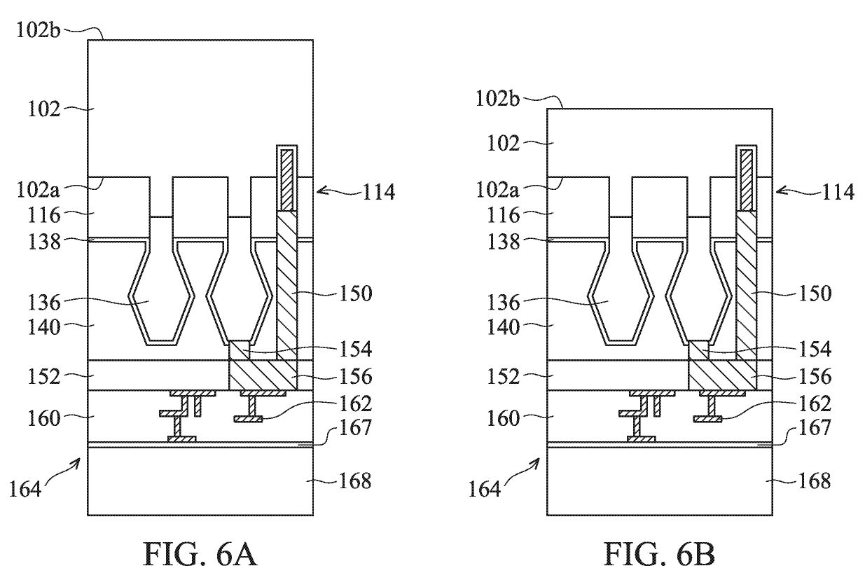

FIG. 6A illustrates a cross-sectional representation of an enlarged semiconductor structure 10 of FIG. 5A, in accordance with some embodiments. FIG. 6B illustrates a cross-sectional representation of an enlarged semiconductor structure 10 of FIG. 5E, in accordance with some embodiments. FIG. 6C illustrates a cross-sectional representation of an enlarged semiconductor structure 10 of FIG. 5F, in accordance with some embodiments.

As shown in FIGS. 5A and 6A, the semiconductor structure 10 in the die or chip form is obtained from FIG. 2C, and the semiconductor structure 10 is turned upside down and placed over a carrier substrate 168 through an adhesive layer 167 (shown in FIG. 6A), in accordance with some embodiments. The backside surface 102b of the substrate 102 is far away from the carrier substrate 168. The front side surface 102a of the substrate 102 is closer to the carrier substrate 168 than the back side surface 102b of the substrate 102.

A device region 190 is formed over the substrate 102. The detain structure of the device region 190 is shown in FIG. 6A, and is not shown in detail in FIG. 5A for clarity. The device region 190 includes all layers and all structures formed over the substrate 102. In some embodiments, the device region 190 includes the conductive plug 114, the isolation structure 116, the S/D structure 136, the CESL 138, the ILD layer 140, the conductive plug 150, the dielectric layer 152, the silicide layer 154, the S/D contact structure 156, the dielectric layer 160, the conductive layer 162 and the interconnect structure 164.

After a serious of fabrication processes are performed on the semiconductor structure 10 in the wafer level, the individual semiconductor structures (or integrated circuits (IC)) on the wafer can be tested through a wafer test system, before they are separated or “diced” from the wafer for packaging. After passing the test, a known good die which has no defects in the integrated circuit (IC) chip is diced from the wafer. In some embodiments, the semiconductor structure 10 is an integrated circuit (IC) die which is sawed from a wafer, and is a “known good die”. Therefore, the semiconductor structure 10 is in a die or chip form, not a wafer form. In some embodiments, the IC die is a logic die, a memory die or another applicable type of die.

The adhesive layer 167 is used as a temporary adhesive layer. The adhesive layer 167 may be glue or a tape. In some embodiments, the adhesive layer 167 is photosensitive and is easily detached from the carrier substrate 118 by light irradiation. For example, shining ultra-violet (UV) light or laser light on the carrier substrate 168 is used to detach the adhesive layer. In some embodiments, the adhesive layer 167 is a light-to-heat-conversion (LTHC) coating. In some other embodiments, the adhesive layer 167 is heat-sensitive and is easily detached from the carrier substrate 168 when it is exposed to heat.

The original substrate 102 has the first thickness T₁ along the vertical direction. In some embodiments, the first thickness T₁ of the substrate 102 is in a range from about 10µm to about 30µm.

Afterwards, as shown in FIG. 5B, a buffer layer 176 is formed on the backside surface 102b of the substrate 102, a sidewall surface of the substrate 102, and on the carrier substrate 168, in accordance with some embodiments. The substrate 102 is in direct contact with the buffer layer 176. The buffer layer 176 is used to improve the polishing uniformity of the substrate 102 during the planarization process (e.g. CMP process).

In some embodiments, the buffer layer 176 is made of oxide, such as silicon oxide. In some embodiments, the buffer layer 176 is formed by a LPCVD process, plasma enhanced CVD (PECVD) process, high density plasma CVD (HDP-CVD) process, high aspect ratio process (HARP) process, flowable CVD (FCVD) process, atomic layer deposition (ALD) process, another suitable method, or a combination thereof.

Next, as shown in FIGS. 5C and 5C’, the buffer layer 176 is patterned to form openings 179, in accordance with some embodiments. The backside surface 102b of the substrate 102 is exposed by the openings 179. The semiconductor structure 10 is surrounded by the buffer layer 176.

In some embodiments, the buffer layer 176 is patterned by a patterning process. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process may include a dry etching process or a wet etching process.

Next, as shown in FIG. 5D, a planarization process is performed on the buffer layer 176 and the substrate 102, in accordance with some embodiments. The top portion of the buffer layer 176 and the top portion of the substrate 102 of the semiconductor structure 10 are simultaneously removed by the planarization process.

The planarization process may include a chemical mechanical polishing (CMP) process, a grinding process, an etching process, another applicable process, or a combination thereof. In some embodiments, the planarization process includes a multiple CMP processes.

By forming the buffer layer 176 surrounding the substrate 102 of the semiconductor structure 102, the down-force between the target backside surface 102b of the substrate 102 and the polishing surface of the polishing pad is more uniform, and therefore the topography variations of the substrate 102 can be controlled well.

During the planarization process, the topography variations of the substrate 102 are gradually decreased as the thickness of the substrate 102 is gradually decreased. As a result, the substrate 102 has a more uniform and smooth topography.

The CMP process involves applying an abrasive in a solution (named as a slurry) to the surface of the substrate 102, and then polishing the surface. Additives in the solution chemically react with the surface material, softening it, and the highest features of the substrate 102 and the buffer layer 176 are removed by the abrasive particles of the CMP process.

In a compared embodiment, a SiGe layer is formed on the substrate (e.g. Si) to use as a stop layer and to control the removal amount of the substrate. In this embodiments, the buffer layer 176 is formed on and in direct contact with the substrate 102 (e.g. Si), and the other layer (e.g. SiGe layer) is absent on the substrate 102. Therefore, the fabrication cost is reduced.

Afterwards, shown in FIGS. 5E and 6B, after the planarization process, a portion of the substrate 102 is removed, in accordance with some embodiments. In some embodiments, the portion of the substrate 102 is removed from the backside surface 102b of the substrate 102 until the predetermined thickness of the substrate 102 is reached. The thinned substrate 102 has the second thickness T₂ smaller than the first thickness T₁ of the original substrate 102 in FIG. 5A. In some embodiments, the second thickness T₂ of the thinned substrate 102 is in a range from about 0.05µm to about 0.8µm.

After the planarization process, the buffer layer 176 is still surrounding the semiconductor structure 10, and the top surface of the backside surface 102b of the substrate 102 is substantially coplanar with the top surface of the remaining buffer layer 176.

Next, as shown in FIG. 5F and 6C, after the thinned substrate 102 is obtained, through substrate via (TSV) structures 172 are formed in the substrate 102 to connect the conductive plug 114, in accordance with some embodiments. One of the TSV structures 172 is electrically connected to one of the conductive plugs 114. In some embodiments, the conductive plug 114 is formed to connect to power rail. In some other embodiments, the TSV structures 172 may be referred to as through-silicon via. It should be noted that the top surface of the buffer layer 176 is higher than the interface between the conductive plug 114 and the TSV structure 172.

In some embodiments, each of the TSV structures 172 includes a barrier layer 172a and a conductive layer 172b formed on the barrier layer 172a. The barrier layer 172a is made of titanium (Ti), titanium nitride (TiN), tantalum (Ta), tantalum nitride (TaN), or another applicable material. In some embodiments, the barrier layer 172a is formed by using a process such as chemical vapor deposition (CVD), physical vapor deposition (PVD), plasma enhanced CVD (PECVD), plasma enhanced physical vapor deposition (PEPVD), atomic layer deposition (ALD), or another applicable deposition process.

The conductive layer 172b may be made of conductive material. In some embodiments, the conductive layer 172b is made of tungsten (W), ruthenium (Ru), molybdenum (Mo), or the like. In some embodiments, the conductive layer 172b is formed by performing a deposition process, such as chemical vapor deposition (CVD), physical vapor deposition, (PVD), atomic layer deposition (ALD), or another applicable process.

It should be noted that the substrate 102 in the package structure 100a is a single die which is sawed from a wafer, and the substrate 102 is a known good die, and therefore the yield of the package structure 100a is improved.

Furthermore, the buffer layer 176 is used to improve the polishing uniformity of the substrate 102 during the planarization process (e.g. CMP process) without using a SiGe layer. Therefore, the fabrication cost of the package structure 100a is reduced.

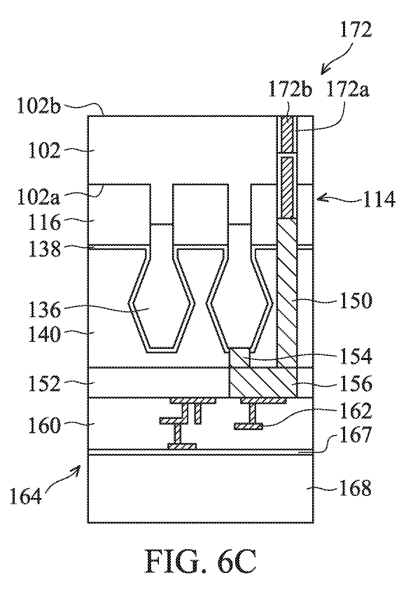

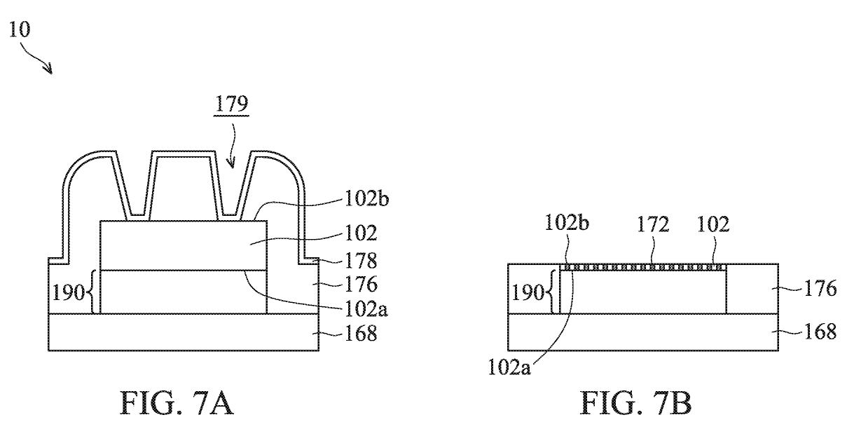

FIGS. 7A-7B illustrate cross-sectional representations of various stages of manufacturing a package structure 100b, in accordance with some embodiments. The package structure 100b of FIG. 7A is similar to, or the same as, the package structure 100a shown in FIG. 5B, except that a stop layer 178 is formed on the buffer layer 176. Processes and materials used to form the package structure 100b may be similar to, or the same as, those used to form the package structure 100a and are not repeated herein.

As shown in FIG. 7A, the stop layer 178 is conformally formed over the buffer layer 176. The material of the stop layer 178 is different from the material of the buffer layer 176. The removal rate of the stop layer 178 is different from that of the buffer layer 176, and therefore the stop layer 178 is used as a removal stop layer while the buffer layer 176 removed.

Note that the CMP process is stopped soon after the stop layer 178 is fully removed to minimize removal of underlying layers. The stop layer 178 can be used as a detection layer to help the CMP process. After the CMP process, the stop layer 178 is completely removed, and the remaining buffer layer 176 is still surrounding the semiconductor structure 10.

In some embodiments, the stop layer 178 is made of silicon nitride, and the buffer layer 176 is made of silicon oxide layer. In some embodiments, the stop layer 178 is formed by a LPCVD process, plasma enhanced CVD (PECVD) process, high density plasma CVD (HDP-CVD) process, high aspect ratio process (HARP) process, flowable CVD (FCVD) process, atomic layer deposition (ALD) process, another suitable method, or a combination thereof.

Afterwards, as shown in FIG. 7B, after performing the planarization process, a portion of the substrate 102 is removed, in accordance with some embodiments. In some embodiments, the portion of the substrate 102 is removed from the backside surface 102b of the substrate 102 until the predetermined thickness of the substrate 102 is reached.

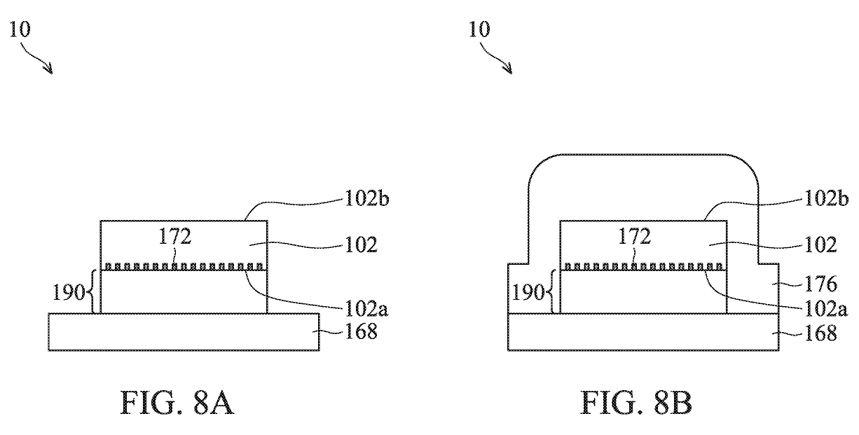

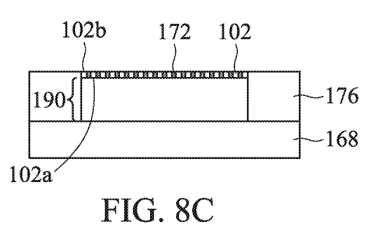

FIGS. 8A-8C illustrate cross-sectional representations of various stages of manufacturing a package structure 100c, in accordance with some embodiments. The package structure 100c of FIG. 8A is similar to, or the same as, the package structure 100a shown in FIG. 5A, except that the TSV structures 172 are formed before the planarization process is performed. Processes and materials used to form the package structure 100c may be similar to, or the same as, those used to form the package structure 100a and are not repeated herein.

As shown in FIG. 8A, the TSV structures 172 are pre-formed in the substrate 102, and the semiconductor structure 10 is turned upside down and placed over the carrier substrate 168, in accordance with some embodiments. One of the TSV structures 172 is electrically connected to one of the conductive plugs 114 before the planarization process. More specifically, before the single die of semiconductor structure 10 is diced from the wafer, the TSV structures 172 are pre-formed in the substrate 102.

Next, as shown in FIG. 8B, the buffer layer 176 is formed on the semiconductor structure 10, in accordance with some embodiments. More specifically, the buffer layer 176 covers the top surface of the backside surface 102b of the substrate 102 and the sidewall surface of the substrate 102. The buffer layer 176 is used to improve the polishing uniformity of the substrate 102 during the planarization process (e.g. CMP process).

Afterwards, as shown in FIG. 8C, after the planarization process, the TSV structures 172 are exposed, in accordance with some embodiments. The exposed top surface of the TSV structure 172 is substantially coplanar with the top surface of the buffer layer 176.

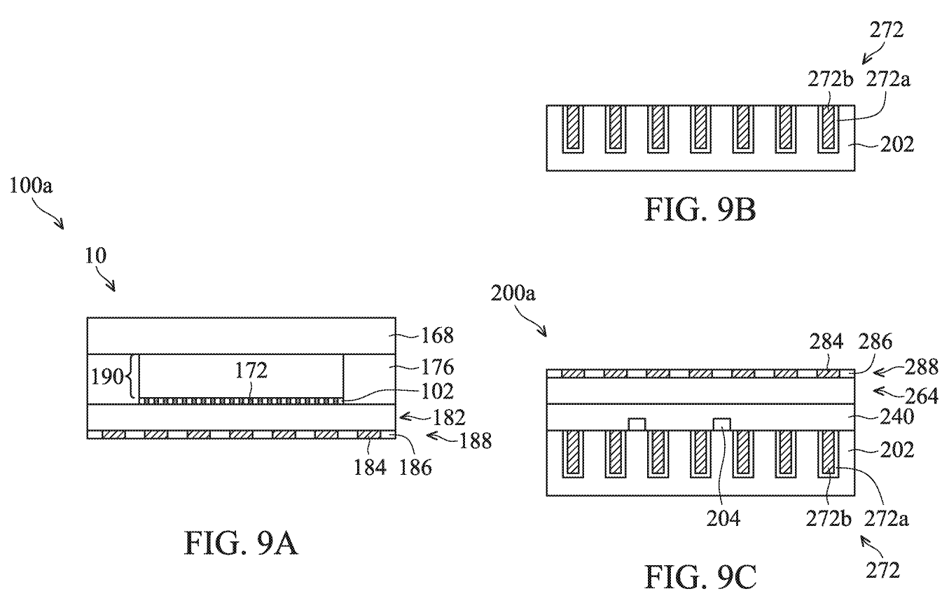

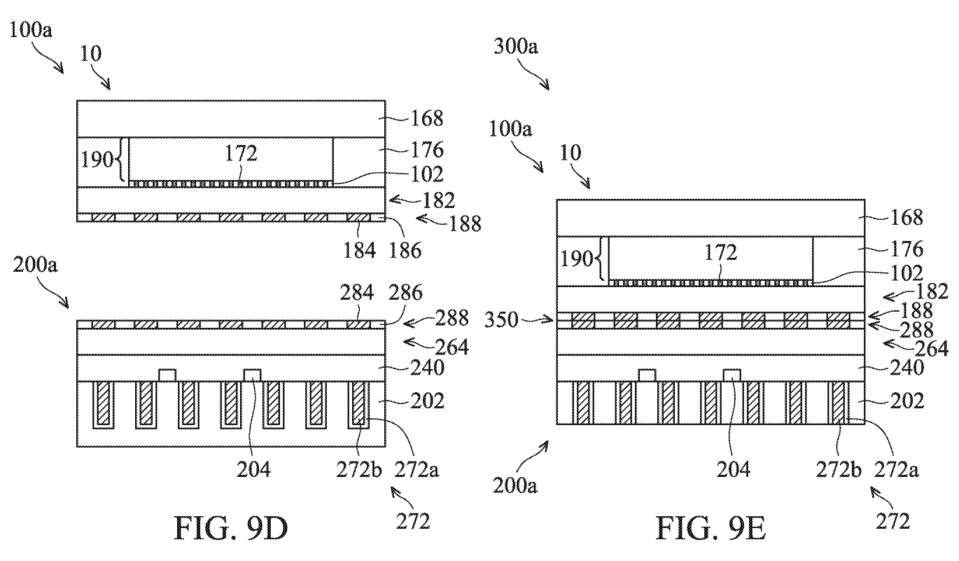

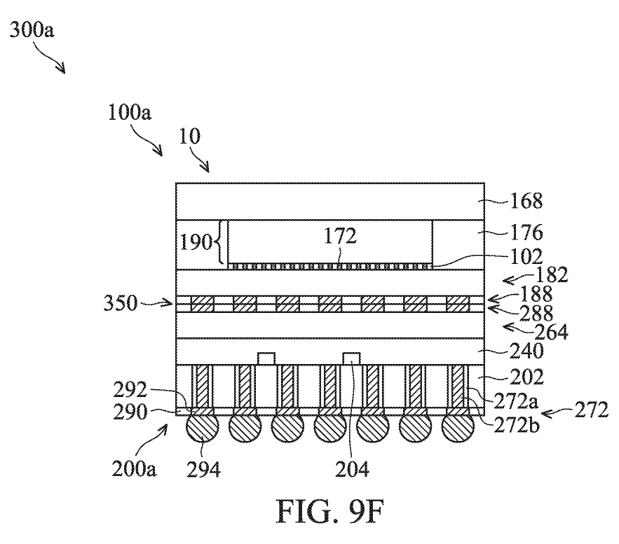

FIGS. 9A-9F illustrate cross-sectional representations of various stages of manufacturing a package structure 300a, in accordance with some embodiments. The package structure 300a may be a chip-on-wafer-on-substrate (CoWoS) package or another suitable package. The package structure 300a may be a system on integrated circuit (SoIC) device that includes two or more chips with integrated functions.

As shown in FIG. 9A, the package structures 100a, 100b or 100c is obtained from FIGS. 5F, 7B, or 8C, and an interconnect structure 182 is formed on the substrate 102 of the package structures 100a, 100b or 100c and the buffer layer 176. Next, a bonding layer 188 is formed on the interconnect structure 182, and the package structure 100a is turned upside down.

The interconnect structure 182 includes conductive layers and vias embedded in the dielectric layers. The interconnect structure 182 shown is merely for illustrative purposes. The interconnect structure 182 may include other configurations and may include one or more conductive lines and via layers.

The first bonding layer 188 includes conductive layers 184 embedded in an insulating layer 186. The conductive layers 184 are contact pads (or bond pads) formed on the top surface of the interconnect structure 182. The conductive layers 184 may be made of conductive materials, such as copper (Cu), copper alloy, aluminum (Al), aluminum alloy, or a combination thereof. Other applicable materials may be used as conductive layer 184. In some embodiments, insulating layer 186 is made of silicon oxide. In some embodiments, insulating layer 186 includes multiple dielectric layers of dielectric materials. In some other embodiments, the insulating layer 186 is made of polymer, such as benzocyclobutene (BCB) polymer, polyimide (PI), polybenzoxazole (PBO), or another applicable material.

Next, as shown in FIG. 9B, the TSV structures 272 are formed in the substrate 202, in accordance with some embodiments. The substrate 202 includes a front surface 202a and a back surface 202b.

Each of the TSV structures 272 may include a barrier layer 272a and a conductive layer 272b on the barrier layer 272a. The barrier layer 272a is made of titanium (Ti), titanium nitride (TiN), tantalum (Ta), tantalum nitride (TaN), or another applicable material. In some embodiments, the barrier layer 272a is formed by using a process such as chemical vapor deposition (CVD), physical vapor deposition (PVD), plasma enhanced CVD (PECVD), plasma enhanced physical vapor deposition (PEPVD), atomic layer deposition (ALD), or another applicable deposition process.

The conductive layer 272b may be made of conductive material. In some embodiments, the conductive layer is made of tungsten (W), ruthenium (Ru), molybdenum (Mo), or the like. In some embodiments, the conductive layer 272b is formed by performing a deposition process, such as chemical vapor deposition (CVD), physical vapor deposition, (PVD), atomic layer deposition (ALD), or another applicable process.

Next, as shown in FIG. 9C, device elements 204 are formed in a dielectric layer 240 over the substrate 202. The device elements 204 include active elements (e.g. transistors, diodes, or the like) and/or passive elements (e.g. resistors, capacitors, inductors, or the like). In some embodiments, the device elements 204 includes a static random access memory (SRAM) device, a dynamic random access memory (DRAM) device, a high bandwidth memory (HBM) device or another memory device. In some embodiments, the device elements 204 include transistors (e.g., metal oxide semiconductor field effect transistors (MOSFET), complementary metal oxide semiconductor (CMOS) transistors, bipolar junction transistors (BJT), high-voltage transistors, high-frequency transistors, p-channel and/or n channel field effect transistors (PFETs/NFETs), etc.), diodes, and/or other applicable elements. Various processes are performed to form device element 204, such as deposition, etching, implantation, photolithography, annealing, and/or other applicable processes. In some embodiments, the device elements 204 are formed in the substrate 202 in a front-end-of-line (FEOL) process.

Afterwards, the interconnect structure 264 is formed over the dielectric layer 240 to form a second package structure 200a. The interconnect structure 264 includes conductive layers and vias embedded in the dielectric layers. The interconnect structure 264 may be used as a redistribution (RDL) structure for routing.

Next, a second bonding layer 288 is formed over the interconnect structure 264. The second bonding layer 288 is similar to the first bonding layer 188. The second bonding layer 288 includes conductive layers 284 embedded in an insulating layer 286. The conductive layers 284 are contact pads (or bond pads) formed on the top surface of the interconnect structure 264. The conductive layers 284 may be made of conductive materials, such as copper (Cu), copper alloy, aluminum (Al), aluminum alloy, or a combination thereof. Other applicable materials may be used as conductive layer 284. In some embodiments, insulating layer 286 is made of silicon oxide. In some embodiments, insulating layer 286 includes multiple dielectric layers of dielectric materials. In some other embodiments, the insulating layer 286 is made of polymer, such as benzocyclobutene (BCB) polymer, polyimide (PI), polybenzoxazole (PBO), or another applicable material.

Afterwards, as shown in FIG. 9D, the first package structure 100a from FIG. 9A and the second package structure 200a from FIG. 9C are aligned, in accordance with some embodiments. More specifically, the conductive layers 184 of the first bonding layers 188 are aligned with the conductive layers 284 of the second bonding layer 288, and the insulating layers 186 of the first bonding layer 188 are aligned with the insulating layers 286 of the second bonding layer 288. In some embodiments, the alignment of the first package structure 100a and the second package structure 200a may be achieved by using an optical sensing method.

The width of the substrate 102 of the first package structure 100a is smaller than the width of the substrate 202 of the second package structure 200a.

Next, as shown in FIG. 9E, after the alignment is performed, the first package structure 100a from FIG. 9A and the second package structure 200a from FIG. 9C are bonded together by hybrid bonding to form the package structure 300a, in accordance with some embodiments. The first package structure 100a and the second package structure 200a are hybrid bonded together by the application of pressure and heat. The hybrid bonding process may be performed in an inert environment, such as an environment filled with inert gas including N₂, Ar, He, or combinations thereof.

As shown in FIG. 9E, a hybrid bonding structure 350 is formed between the first package structure 100a and the second package structure 200a. The hybrid bonding involves at least two types of bonding, including metal-to-metal bonding and non-metal-to-non-metal bonding. The hybrid bonding structure 350 includes conductive layers 184 and 284 bonded by metal-to-metal bonding and the insulating layers 186 and 286 bonded by non-metal-to-non-metal bonding. The bonding structure 350 has a metallic bonding interface between conductive layers 184 and 284 but may not have a clear non-metallic interface between the insulating layers 186 and 286.

Next, a portion of the substrate 202 is removed, in accordance with some embodiments. In some embodiments, the substrate 202 is thinned from the front side surface 202a until the TSV structures 272 are exposed. In some embodiments, the substrate 202 is thinned by a planarization process. The planarization process may include a chemical mechanical polishing (CMP) process, a grinding process, an etching process, another applicable process, or a combination thereof.

Afterwards, as shown in FIG. 9F, a passivation layer 290 is formed below the substrate 202, and the passivation layer 290 is patterned to form a number of openings. The openings expose portions of the TSV structures 272.

The passivation layer 290 is made of dielectric material(s) and provides stress relief for bonding stress incurred during subsequent bonding processes. In some embodiments, the passivation layer 290 is made of PBO, BCB, silicone, acrylates, siloxane, another suitable material, or a combination thereof. In some other embodiments, the passivation layer 290 is made of non-organic materials. The non-organic materials includes silicon oxide, un-doped silicate glass, silicon oxynitride, SR, silicon nitride, silicon carbide, HMDS, another suitable material, or a combination thereof.

Next, UBM layers 292 are formed in the openings, and connectors 294 are formed over the UBM layers 292. The UBM layer 292 may contain an adhesion layer and/or a wetting layer. In some embodiments, the UBM layer 292 is made of titanium (Ti), titanium nitride (TiN), tantalum nitride (TaN), tantalum (Ta), or the like. In some embodiments, the UBM layer 292 further includes a copper seed layer. In some embodiments, the UBM layer 292 connectors 294 are formed by electroplating, electroless plating, printing, a chemical vapor deposition (CVD) process, a physical vapor process, or another applicable process.

The connectors 294 are formed over the passivation layer 290. The connectors 294 are electrically connected to the TSV structures 272. In some embodiments, the connectors 294 are referred to as controlled collapse chip connection (C4) bumps or micro-bumps. The conductive connectors 294 are made of solder materials, such as tin (Sn), tin-silver (SnAg), tin-lead (SnPb), tin-copper (SnCu), tin-silver-copper (SnAgCu), tin-silver-zinc (SnAgZn), tin-zinc (SnZn), tin-bismuth-indium (SnBiIn), tin-indium (SnIn), tin-gold (SnAu), tin-zinc-indium (SnZnIn), tin-silver-Antimony (SnAgSb) or another applicable material. In some embodiments, the conductive connectors 294 are formed by electroplating, electroless plating, printing, a chemical vapor deposition (CVD) process, a physical vapor process, or another applicable process.

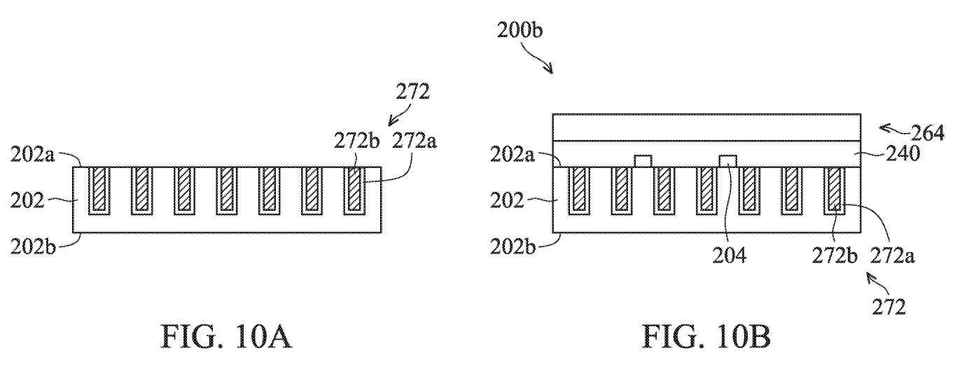

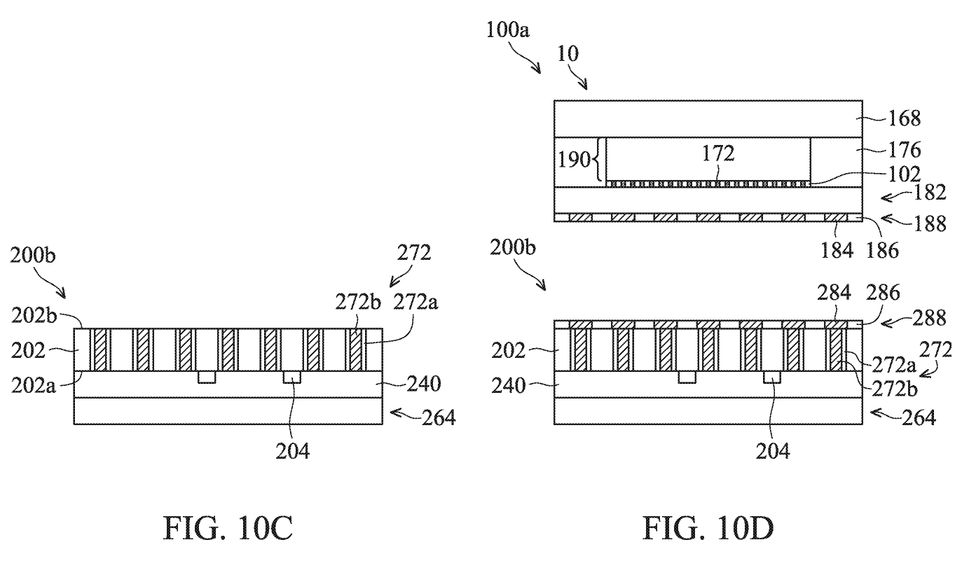

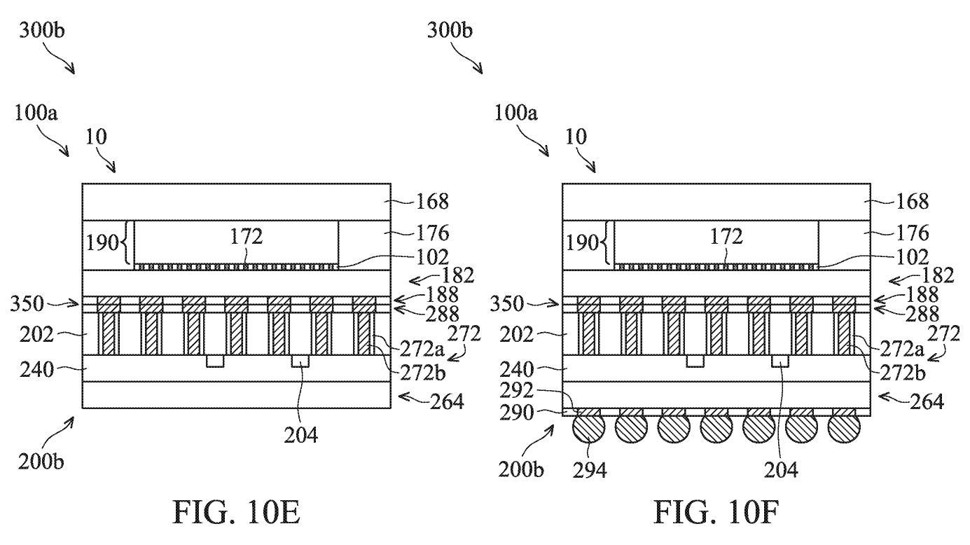

FIGS. 10A-10F illustrate cross-sectional representations of various stages of manufacturing a package structure 300b, in accordance with some embodiments. Processes and materials used to form the package structure 300b may be similar to, or the same as, those used to form the package structure 300a and are not repeated herein.

As shown in FIG. 10A, the TSV structures 272 are formed in the substrate 202, in accordance with some embodiments. The substrate 202 includes a front side surface 202a and a backside surface 202b. The TSV structures 272 are formed from the front side surface 202a of the substrate 202.

Each of the TSV structures 272 may include a barrier layer 272a and a conductive layer 272b on the barrier layer 272a. The barrier layer 272a is made of titanium (Ti), titanium nitride (TiN), tantalum (Ta), tantalum nitride (TaN), or another applicable material. In some embodiments, the barrier layer 272a is formed by using a process such as chemical vapor deposition (CVD), physical vapor deposition (PVD), plasma enhanced CVD (PECVD), plasma enhanced physical vapor deposition (PEPVD), atomic layer deposition (ALD), or another applicable deposition process.

The conductive layer 272b may be made of conductive material. In some embodiments, the conductive layer is made of tungsten (W), ruthenium (Ru), molybdenum (Mo), or the like. In some embodiments, the conductive layer 272b is formed by performing a deposition process, such as chemical vapor deposition (CVD), physical vapor deposition, (PVD), atomic layer deposition (ALD), or another applicable process.

Next, as shown in FIG. 10B, the dielectric layer 240 is formed over the TSV structures 272 over the substrate 202, and the device elements 204 are formed in the dielectric layer 240, in accordance with some embodiments. In some embodiments, the device elements 204 includes a static random access memory (SRAM) device, a dynamic random access memory (DRAM) device, a high bandwidth memory (HBM) device or another memory device. In some embodiments, the device elements 204 include active elements (e.g. transistors, diodes, or the like) and/or passive elements (e.g. resistors, capacitors, inductors, or the like). In some embodiments, the device elements 204 include transistors (e.g., metal oxide semiconductor field effect transistors (MOSFET), complementary metal oxide semiconductor (CMOS) transistors, bipolar junction transistors (BJT), high-voltage transistors, high-frequency transistors, p-channel and/or n channel field effect transistors (PFETs/NFETs), etc.), diodes, and/or other applicable elements. Various processes are performed to form device elements 204, such as deposition, etching, implantation, photolithography, annealing, and/or other applicable processes. In some embodiments, the device elements 204 are formed in the substrate 202 in a front-end-of-line (FEOL) process.

Afterwards, the interconnect structure 264 is formed over the dielectric layer 240. The interconnect structure 264 includes conductive layers and vias embedded in the dielectric layers.

Afterwards, as shown in FIG. 10C, the substrate 202 is turned upside down and a portion of the substrate 202 is removed to form a second package structure 200b, in accordance with some embodiments. The portion of the substrate 202 is removed from the backside surface 202b by a planarization process to expose the TSV structures 272. The planarization process may include a chemical mechanical polishing (CMP) process, a grinding process, an etching process, another applicable process, or a combination thereof.

Next, as shown in FIG. 10D, the second bonding layer 288 is formed over the exposed TSV structures 272 and the backside surface 202b of the substrate 202, and the first package structure 100a from FIG. 9A and the second package structure 200b from FIG. 10C are aligned, in accordance with some embodiments.

The second bonding layer 288 is similar to the first bonding layer 188. The second bonding layer 288 includes conductive layers 284 embedded in an insulating layer 286. More specifically, the conductive layers 184 of the first bonding layers 188 are aligned with the conductive layers 284 of the first bonding layer 288, and the insulating layers 186 of the first bonding layer 188 are aligned with the insulating layers 286 of the second bonding layer 288. In some embodiments, the alignment of the first package structure 100a and the second package structure 200b may be achieved by using an optical sensing method.

Afterwards, as shown in FIG. 10E, after the alignment is performed, the first package structure 100a from FIG. 9A and the second package structure 200b from FIG. 10C are bonded together by hybrid bonding to form the package structure 300b, in accordance with some embodiments. The first package structure 100a and the second package structure 200b are hybrid bonded together by the application of pressure and heat. The hybrid bonding process may be performed in an inert environment, such as an environment filled with inert gas including N₂, Ar, He, or combinations thereof.

As shown in FIG. 10E, the hybrid bonding structure 350 is formed between the first package structure 100a and the second package structure 200b. The hybrid bonding involves at least two types of bonding, including metal-to-metal bonding and non-metal-to-non-metal bonding. The hybrid bonding structure 350 includes conductive layers 184 and 284 bonded by metal-to-metal bonding and the insulating layers 186 and 286 bonded by non-metal-to-non-metal bonding.

Next, as shown in FIG. 10F, the passivation layer 290 is formed below the interconnect structure 264, and the passivation layer 290 is patterned to form a number of openings, in accordance with some embodiments. Next, the UBM layer 292 are formed in the openings, and the connectors 294 are formed over the UBM layer 292.

The passivation layer 290 is made of dielectric material(s) and provides stress relief for bonding stress incurred during subsequent bonding processes. In some embodiments, the passivation layer 290 is made of PBO, BCB, silicone, acrylates, siloxane, another suitable material, or a combination thereof. In some other embodiments, the passivation layer 290 is made of non-organic materials. The non-organic materials includes silicon oxide, un-doped silicate glass, silicon oxynitride, SR, silicon nitride, silicon carbide, HMDS, another suitable material, or a combination thereof.

The connectors 294 are formed over the passivation layer 290. The connectors 294 are electrically connected to the TSV structures 272 by the conductive layers of the interconnect structure 264. In some embodiments, the connectors 294 are referred to as controlled collapse chip connection (C4) bumps or micro-bumps.

The first package structure 100a, 100b or 100c is bonded to the second package structure 200a or 200b to form the hybrid bonding package structure 300a or 300b. The first die of the package structure 100a, 100b or 100c is diced from a wafer and is a known good die which passed through test. Since the first die is a known good die, and yield and the reliability are improve. In addition, the substrate 102 of the first die is thinned by using the buffer layer without using SiGe layer to form TSV structures 172. The fabrication cost is reduced.

Embodiments of methods for forming a package structure are provided. The semiconductor structure is firstly formed to include device formed over a substrate, and a conductive plug formed in the substrate. The known good die including the semiconductor structure is obtained from a wafer. Next, the know good die in a die or chip form is turned upside down and placed over a carrier substrate. The backside of the substrate is exposed, and a buffer layer is formed over the backside surface of the substrate. The buffer layer is used to improve the polishing uniformity of the substrate during the planarization process (e.g. CMP process). A planarization process is performed on a portion of the buffer layer and a portion of the substrate to form a thinned substrate. The TSV structures are formed in the thinned substrate to connect the conductive plug which is formed before the planarization process. Since the die is a known good die, and the polishing uniformity of the substrate is controlled well by the help of the buffer layer. Therefore, the yield, the quality and reliability of the package structure are improved.

In some embodiments, a method for forming a package structure is provided. The method includes forming a first die over a carrier substrate, and the first die includes a first substrate with a first thickness and a first conductive plug formed in the first substrate. The method also includes forming a buffer layer over the first die and the first substrate, and the buffer layer covers the top surface and the sidewall surface of the first die. The method includes removing a portion of the buffer layer to form a trench in the buffer layer, and the first substrate is exposed by the trench. The method includes performing a planarization process on the buffer layer and the first substrate of the first die to form a thinned first substrate, and the thinned first substrate has a second thickness smaller than the first thickness. After the planarization process, the method includes forming through substrate via (TSV) structures in the thinned first substrate. One of the TSV structures is electrically connected to the first conductive plug.

In some embodiments, a method for forming a package structure is provided. The method includes forming a first die over a carrier substrate, and the first die includes a first substrate and a first conductive plug formed in the first substrate. The method includes forming a buffer layer on the first die, and the first die is surrounded by the buffer layer. The method also includes removing a portion of the buffer layer and a portion of the first substrate to form a thinned first substrate surrounded by the remaining buffer layer. The method includes forming a first bonding layer on the thinned first substrate and the remaining buffer layer to form a first package structure. The method includes bonding the first package structure to a second package structure by bonding the first bonding layer to a second bonding layer.

In some embodiments, a package structure is provided. The package structure includes a first package structure and a second package structure. The first package structure includes a first device, and the first device comprises an S/D structure formed over a first substrate, a conductive plug adjacent to the S/D structure, a plurality of first through substrate via (TSV) structures connected to the conductive plug; and a first bonding layer formed over the first substrate. The second package structure comprises a second device formed over a second substrate, and a second bonding layer formed over the second device. The package structure includes a bonding structure between the first package structure and the second package structure, and the bonding structure comprises the first bonding layer and the second bonding layer.

In some embodiments, a package structure is provided. The package structure includes a first package structure and a second package structure. The first package structure includes a plurality of nanostructures formed over a first substrate, a gate structure formed on the nanostructures, an S/D structure adjacent to the gate structure, an S/D contact structure formed over the S/D structure, a conductive plug adjacent to the S/D structure, a plurality of first through substrate via (TSV) structures connected to the conductive plug, and a first interconnect structure below the first TSV structures. The second package structure comprises a second device formed over a second substrate, and a width of the first substrate is smaller than a width of the second substrate.

In some embodiments, a package structure is provided. The package structure includes a first package structure and a second package structure. The first package structure includes a first device formed over a first substrate. The first device includes a first conductive plug connected to a through substrate via (TSV) structure formed in the first substrate. A buffer layer surrounding the first substrate, and a first bonding layer formed over the first substrate and the buffer layer. The second package structure includes a second device formed over a second substrate, and a second bonding layer formed over the second device. A hybrid bonding structure is between the first package structure and the second package structure by bonding the first bonding layer to the second bonding layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first package structure, wherein the first package structure comprises:
a first device, wherein the first device comprises:
an S/D structure formed over a first substrate;
a conductive plug adjacent to the S/D structure;
a plurality of first through substrate via (TSV) structures connected to the conductive plug; and
a first bonding layer formed over the first substrate;
a second package structure, wherein the second package structure comprises:
a second device formed over a second substrate; and
a second bonding layer formed over the second device; and
a bonding structure between the first package structure and the second package structure, wherein the bonding structure comprises the first bonding layer and the second bonding layer.

2. The package structure as claimed in claim 1, wherein the first package structure further comprises a buffer layer surrounding the first substrate.

3. The package structure as claimed in claim 1, wherein the second package structure further comprises a plurality of second through substrate via (TSV) structures.

4. The package structure as claimed in claim 3, wherein the second TSV structures are connected to the second bonding layer.

5. The package structure as claimed in claim 1, wherein the bonding structure comprises a first conductive material embedded in a first insulating layer and a second conductive material embedded in a second insulating layer.

6. The package structure as claimed in claim 1, wherein the first device further comprises a plurality of nanostructures formed over the first substrate, and a gate structure formed on the nanostructures.

7. The package structure as claimed in claim 1, wherein the first TSV structures are closer to a back-side surface of the S/D structure than a front-side surface of the S/D structure.

8. The package structure as claimed in claim 1, further comprising:
an interconnect structure between the first TSV structures and the bonding structure.

9. The package structure as claimed in claim 1, further comprising:
an isolation structure formed over the first substrate, wherein the first TSV structures are through the isolation structure.

10. A package structure, comprising:
a first package structure, wherein the first package structure comprises:
a first device, wherein the first device comprises:
a plurality of nanostructures formed over a first substrate;
a gate structure formed on the nanostructures;
an S/D structure adjacent to the gate structure;
an S/D contact structure formed over the S/D structure;
a conductive plug adjacent to the S/D structure;
a plurality of first through substrate via (TSV) structures connected to the conductive plug; and
a first interconnect structure below the first TSV structures; and
a second package structure below the first package structure, wherein the second package structure comprises a second device formed over a second substrate, and a width of the first substrate is smaller than a width of the second substrate.

11. The package structure as claimed in claim 10, wherein the first package structure further comprises a buffer layer surrounding the first substrate.

12. The package structure as claimed in claim 10, wherein the second package structure further comprises a plurality of second through substrate via (TSV) structures through the second substrate.

13. The package structure as claimed in claim 12, wherein the second package structure further comprises a second interconnect structure, and the second interconnect structure is between the first interconnect structure and the second TSV structures.

14. The package structure as claimed in claim 10, further comprising:
an isolation structure formed over the substrate, wherein the first TSV structures are through the isolation structure.

15. The package structure as claimed in claim 13, wherein an interface between the conductive plug and the first TSV structures are below a bottom surface of the isolation structure.

16. A package structure, comprising:
a first package structure, wherein the first package structure comprises:
a first device formed over a first substrate, wherein the first device comprises a first conductive plug connected to a through substrate via (TSV) structure formed in the first substrate;
a buffer layer surrounding the first substrate; and
a first bonding layer formed over the first substrate and the buffer layer; and
a second package structure, wherein the second package structure comprises:
a second device formed over a second substrate; and
a second bonding layer formed over the second device; and
a hybrid bonding structure between the first package structure and the second package structure by bonding the first bonding layer to the second bonding layer.

17. The package structure as claimed in claim 16, wherein the hybrid bonding structure comprises a first conductive material embedded in a first insulating layer and a second conductive material embedded in a second insulating layer.

18. The package structure as claimed in claim 16, wherein a width of the first substrate is smaller than a width of the second substrate.

19. The package structure as claimed in claim 16, wherein the second package structure further comprises through substrate via (TSV) structures.

20. The package structure as claimed in claim 16, wherein the first device further comprises:
nanostructures formed over the first substrate;
an S/D structure formed adjacent to the nanostructures;
an S/D contact structure formed over the S/D structure; and
a second conductive plug connected to the first conductive plug and the S/D contact structure.
